(19) United States
(12) Patent Application Publication
(10) Pub. No.: US 2007/0274054 A1
(43) Pub. Date: Nov. 29, 2007

(54) Foolproof interlock apparatus

(75) Inventors: Shao-An Lu, Taoyuan County (TW); Liang-Ta Yeh, Taipei County (TW)

Correspondence Address: BIRCH STEWART KOLASCH & BIRCH, PO BOX 747, FALLS CHURCH, VA, 22040-0747, US

(73) Assignee: Darfon Electronics Corp.

(21) Appl. No.: 11/798,138

(22) Filed: May 10, 2007

(30) Foreign Application Priority Data
May 23, 2006 (TW) 095118243

(51) Int. Cl. H05K 7/16

(52) U.S. Cl. 361/727

(57) ABSTRACT

The present invention relates to a foolproof interlock apparatus, adapted to enable a first device to interlock with a second device, which comprises: at least a hook, composed of an extending part and a engaging part; and at least a lip having a recess; wherein, the engaging part is disposed at a free end of the extending part while an end of the extending part is fitted to the first device; and the recess of the lip fitted to the second device is used to receive the engaging part for enabling the recess and the engaging part to abut against each other and thus maintain a specific engagement. Therefore, by adjusting the engagement between the hook and the lip, the tightness of the engagement between the first and the second device can be controlled.

### FIELD OF THE INVENTION

The present invention relates to a foolproof interlock apparatus, and more particularly to a hook structure, adapted for enabling a battery cover to interlock with a housing, in which a recess of a lip fitted to the housing is used to receive a hook of the hook structure for enabling the recess and the hook to abut against each other and thus maintain a specific engagement, therefore, by adjusting the engagement between the hook and the lip, the tightness of the engagement can be controlled

### BACKGROUND OF THE INVENTION

Conventionally, hook structure is used extensively in the design of connecting various different devices, such as for the assembling a front and a rear shells or an upper and lower casings of a device, or for assembling a battery cover and a device body, and so on.

Taking an interlock apparatus for connecting a battery cover to a housing for example, it is noted that any conventional device using battery as its power source such as radios, calculators, or wireless mice, usually is designed with a battery cover upon its housing at a position corresponding to the disposition of its battery. Regardless of the type of the battery, most such devices preferred to have a detachable battery cover that is ease to detach and assemble for facilitating battery replacement. In general, the interlock apparatus is comprised of: a hook, fitted onto the battery cover; and a slot, formed on the housing at a position corresponding to the hook; wherein by engaging the hook with the slot, the battery cover is fixedly assembled to the housing. In most cases, the hook can be made of a plastic or metal material depending on the practical requirements, whereas the housing can be made of a plastic material such as ABS or PC. Without any special requirement, the hook is usually integrally formed with the battery cover. In view of the mechanical design of the interlock apparatus, the engagement of the hook and the slot must be tight enough to provide a certain bonding force which can pull and assemble the battery cover and the housing tightly together, but still it should be loose enough for an user to separate the battery cover from the housing easily. Compared with those used for connecting a front casing to a rear casing, or those connecting an upper casing to a lower casings, the interlock apparatus for assembling a battery cover to a housing is much more difficult to design. Although a specific engagement is specified in the design of an interlock apparatus for battery cover, the dimensions may be deviated from the original design due to a posterior manufacturing process such as a paint spray or baking process, so that the tightness of opening or closing a battery cover is not consistent, and thus the defective rate is increased. For those produced with too much engagement, although they can be rectified by a cutting process, it will consumes much manufacturing time and incurs high manufacturing costs.

### SUMMARY OF THE INVENTION

Therefore, it is a primary objective of the invention to overcome the shortcomings of the prior art by providing a foolproof interlock apparatus, not only capable of being used for assembling a battery cover with a housing, but also for engaging a first device with a second device, in which a specific engagement can be maintained while engaging a hook with its corresponding lip, and thus an engagement of a constant tightness can be maintain between the first device and the second device that is not too tight and not too loose, thereby, the yield can be increased.

To achieve the foregoing objective, the present invention provides a foolproof interlock apparatus, adapted to enable a first device to interlock with a second device, comprising:
at least a hook further comprised of an engaging part, disposed on the first device; and
at least a lip with a recess, disposed on the second device for engaging with the engaging part of the hook;
wherein, the recess of the lip fitted to the second device is used to receive the engaging part for enabling the recess and the engaging part to abut against each other.

Preferably, the recess and the engaging part are engaged by a specific engagement.

Preferably, the hook further comprises an extending part protruded from the first device while structuring its protruding rear to be a free end provided for the engaging part to fitted thereon.

Preferably, the extending part is shaped as a flat sheet.

Preferably, the extending part is substantially in a flat rectangular-shaped sheet, having a lateral edge connecting to an engaging end of the first device and an opposing lateral edge being structured as a free end.

Preferably, the engaging part of the hook, being a rectangular-shaped part, is extendedly connected to the free end of the extending part.

Preferably, the first device is a battery cover while the second device is a housing capable of being engaged with the battery cover to form a whole device.

Preferably, the second device is a housing of a computer mouse.

Preferably, the hook is fitted on the battery cover while the lip is disposed on the housing.

Preferably, the hook is fitted on the battery cover at a surface thereof facing toward the housing, and the lip is formed on the housing at a position corresponding to the hook.

Preferably, the second device is a housing of device selected from the group consisting of a computer, a cell phone, or a personal digital assistant (PDA).

### BRIEF DESCRIPTION OF THE DRAWINGS

FIG. 1 is a perspective view of an interlock apparatus adapted for connecting a battery cover and a mouse according to a preferred embodiment of the present invention.

FIG. 2 is another perspective view of FIG. 1 being viewed from viewing angle different than that of FIG. 1 while only a top shell of the mouse is illustrated.

FIGS. 3A and 3B are schematic views of the engaging of a hook and a lip according to the present invention.

FIG. 4 is an enlarged view of section A of FIG. 3B.

### DESCRIPTION OF THE PREFERRED EMBODIMENT

To make it easier for our examiner to understand the objective of the invention, its structure, innovative features, and performance, we use a preferred embodiment together with the attached drawings for the detailed description of the invention.

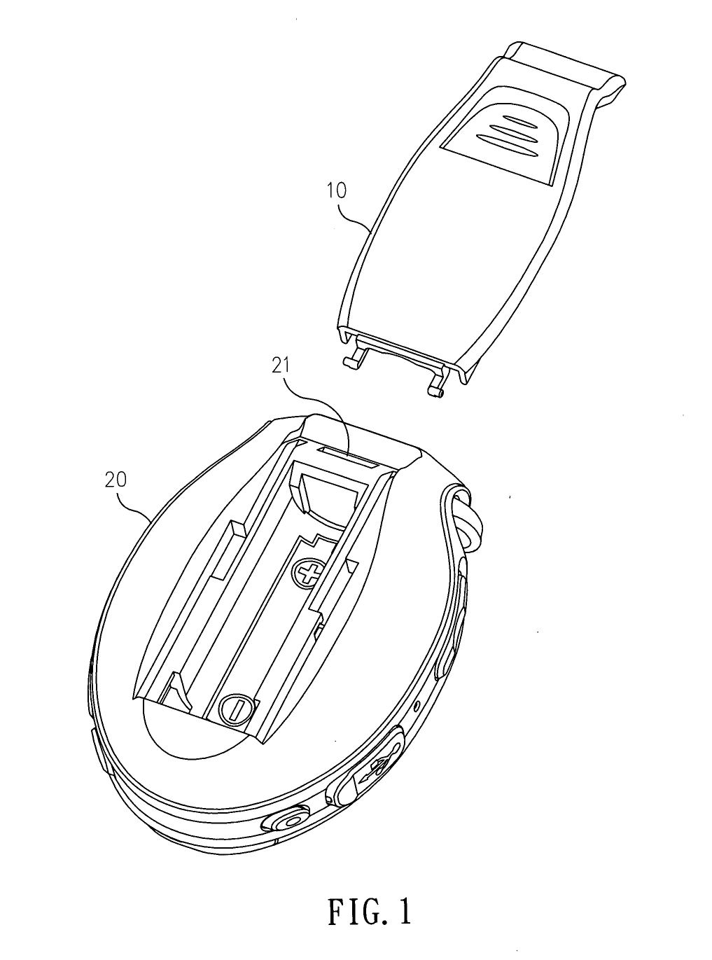

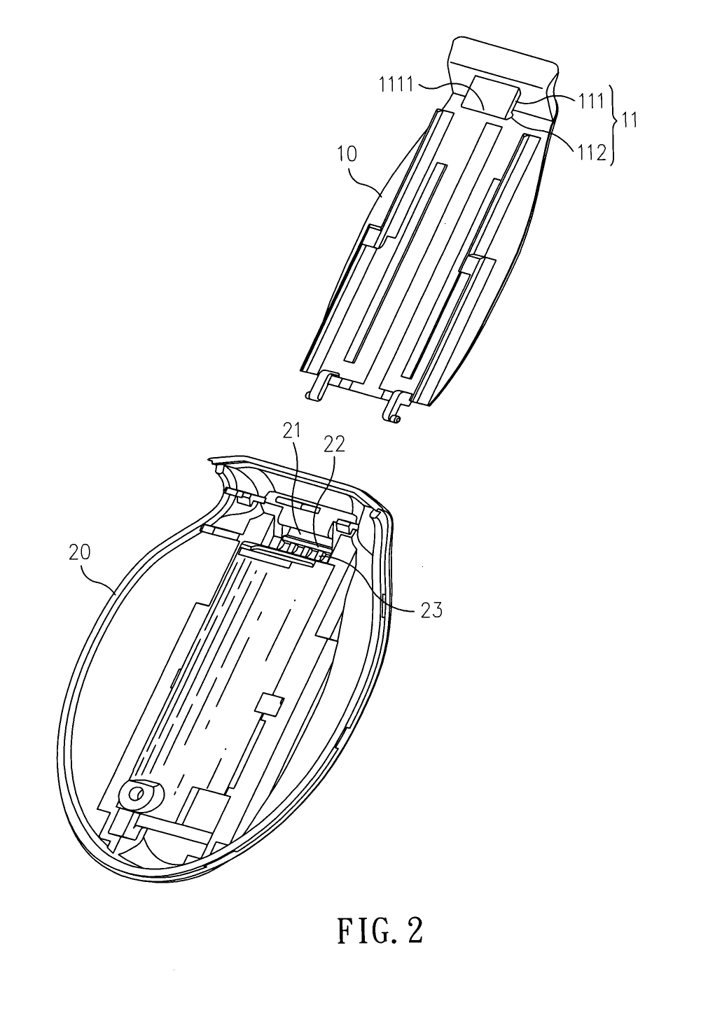

Referring to FIGS. 1 and 2, a foolproof interlock apparatus in accordance with the present invention is adapted to enable a first device to interlock with a second device, whereas the first device is a battery cover 10, and the second device is a housing of computer mouse 20. Wherein the battery cover 10 and the housing 20 can be engaged to form a complete housing of a mouse. To illustrate the structure of a foolproof interlock apparatus of the present invention more clearly, FIG. 2 has not shown the whole housing 20, but only its upper casing. In addition to the housing 20, the second device is not limited to the computer mouse, it can be a device selected from the group consisting of a computer, a cell phone, a personal digital assistant (PDA) and the likes.

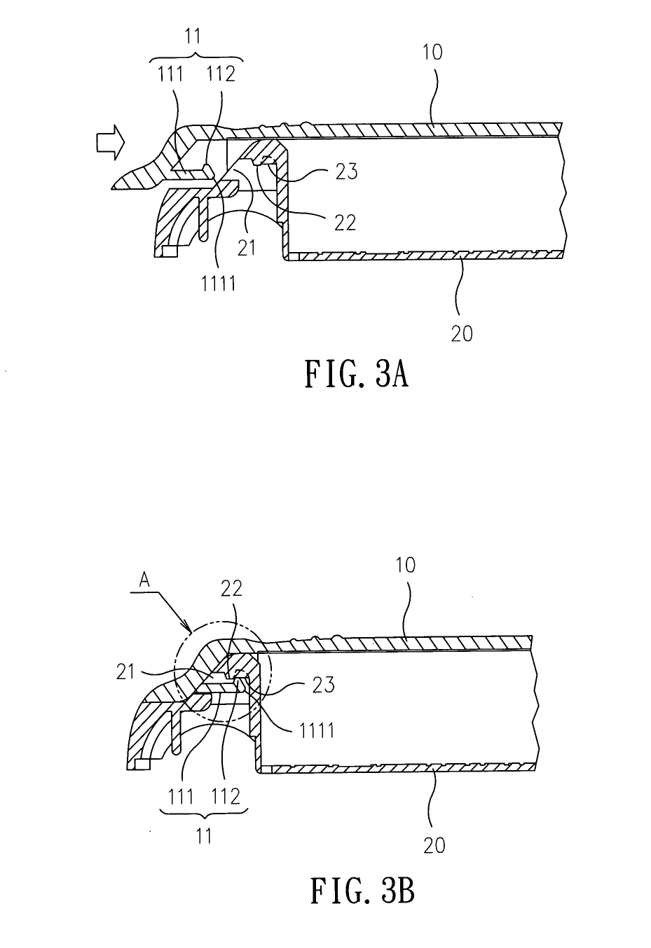

Referring to FIGS. 2 to 4, the battery cover 10 has a hook 11, composed of an extending part 111 and an engaging part 112, and the extending part 111 is protruded from an internal sidewall of the battery cover 10, and its protruding rear end constitutes a free end 1111, and the engaging part 112 is installed at the free end 1111. The extending part 111 as shown in the figures is substantially in a rectangular sheet shape, and the free end 1111 of the extending part 111 is extended to constitute a rectangular engaging part 112. The housing 20 has a penetrating part 21, and a lip 22 disposed in the housing 20, wherein the penetrating part is provided for extending the protruded hook 11 into the housing 20, and the engaging part 112 of the hook 11 is engaged with the lip 22 (as shown in FIG. 3B).

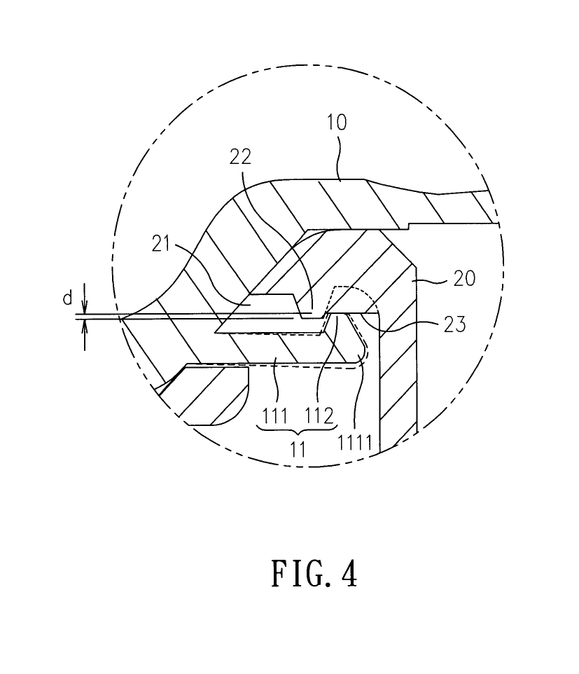

Referring to FIG. 4, the internal side of the lip 22 has a recess 23 with a height slightly lower than the top of the lip 22 for receiving the engaging part 12 engaged with the lip 22. Preferably, the recess 23 and the engaging part 12 abut with each other and are engaged by a specific engagement. Even if the dimensions of engaging part 112 are deviated from the original design (indicated by the dotted lines around the periphery of the engaging part 112 as shown in FIG. 4) due to the paint spray and baking processes, such that when the extending part 111, the engaging part 12, the lip 22 and the recess 23 are deformed during their engagement, the engaging part 12 and the lip 22 still can maintain a specific engagement d. As a result, the force applied onto the lip 22 for withdrawing from the engaging part 112 remains unchanged to control the tightness of engaging the battery cover 10 with the housing 20, and the battery cover 10 will not be too tight or too loose.

In summation of the description above, the foolproof interlock apparatus of the present invention not only is capable of being used for assembling a battery cover with a housing, but also is used for engaging a first device with a second device, in which a specific engagement can be maintained while engaging a hook with its corresponding lip, and thus an engagement of a constant tightness can be maintain between the first device and the second device that is not too tight and not too loose, thereby, the yield can be increased.

Other aspects and advantages of the present invention will become apparent from the following detailed description, taken in conjunction with the accompanying drawings, illustrating by way of example the principles of the present invention.

What is claimed is:

1. A foolproof interlock apparatus, comprising:
at least a hook with an engagement part, each disposed on a first device; and
at least a lip having a recess dropped from the top of the lip by a specific height, disposed on a second device for interlocking with the engaging part of the hook;
wherein, the recess is designed to receive the engaging part while enabling the recess and the engaging part to abut against each other.

2. The foolproof interlock apparatus as recited in claim 1, wherein the recess and the engaging part are interfered and engaged with each other.

3. The foolproof interlock apparatus as recited in claim 1, wherein each hook further comprises an extending part protruded from the first device while structuring its protruding rear to be a free end provided for the engaging part to fit thereon.

4. The foolproof interlock apparatus as recited in claim 3, wherein the extending part is shaped as a flat sheet.

5. The foolproof interlock apparatus as recited in claim 4, wherein the extending part is substantially in a flat rectangular-shaped sheet, having a lateral edge connecting to an engaging end of the first device and an opposing lateral edge being structured as a free end.

6. The foolproof interlock apparatus as recited in claim 5, wherein the engaging part of the hook, being a rectangular-shaped part, is extendedly connected to the free end of the extending part.

7. The foolproof interlock apparatus as recited in claim 1, wherein the first device is a battery cover while the second device is a housing capable of being engaged with the battery cover to form a whole device.

8. The foolproof interlock apparatus as recited in claim 7, wherein the second device is a housing of a computer mouse.

9. The foolproof interlock apparatus as recited in claim 7, wherein the hook is fitted on the battery cover while the lip is disposed on the housing.

10. The foolproof interlock apparatus as recited in claim 9, wherein the hook is fitted on the battery cover at a surface thereof facing toward the housing, and the lip is formed on the housing at a position corresponding to the hook.

11. A foolproof interlock apparatus, adapted to enable a first device to interlock with a second device, comprising:
at least a hook, composed of an extending part and a engaging part; and
at least a lip, having a recess dropped from the top of the lip by a specific height; for engaging with the engaging part of its corresponding hook;
wherein, the engaging part is disposed at a free end of the extending part in a protruding manner while an end of the extending part is fitted to the first device; and the recess of the lip fitted to the second device is used to receive the engaging part for enabling the recess and the engaging part to abut against each other and thus maintain a specific engagement.

12. The foolproof interlock apparatus as recited in claim 11, wherein the recess and the engaging part are interfered and engaged with each other.

13. The foolproof interlock apparatus as recited in claim 11, wherein the extending part is shaped as a flat sheet.

14. The foolproof interlock apparatus as recited in claim 13, wherein the extending part is substantially in a flat rectangular-shaped sheet, having a lateral edge connecting to an engaging end of the first device and an opposing lateral edge being structured as a free end.

15. The foolproof interlock apparatus as recited in claim 14, wherein the engaging part of the hook, being a rectangular-shaped part, is extendedly connected to the free end of the extending part.

16. The foolproof interlock apparatus as recited in claim 11, wherein the first device is a battery cover while the second device is a housing capable of being engaged with the battery cover to form a whole device.

17. The foolproof interlock apparatus as recited in claim 16, wherein the second device is a housing of a computer mouse.

18. The foolproof interlock apparatus as recited in claim 16, wherein the hook is fitted on the battery cover while the lip is disposed on the housing.

19. The foolproof interlock apparatus as recited in claim 18, wherein the hook is fitted on the battery cover at a surface thereof facing toward the housing, and the lip is formed on the housing at a position corresponding to the hook.

20. The foolproof interlock apparatus as recited in claim 11, wherein the second device is a housing of device selected from the group consisting of a computer, a cell phone, or a personal digital assistant (PDA).
